(19) United States
(12) Patent Application Publication
(10) Pub. No.: US 2026/0349054 A1
(43) Pub. Date: Nov. 5, 2026

(54) MAGNETIC FIELD MICROPROBE BASED ON ANOMALOUS NERNST EFFECT AND CALIBRATION AND APPLICATION METHOD THEREFOR

(71) Applicant: CHINA JILIANG UNIVERSITY, Hangzhou (CN)

(72) Inventors: XIUKUN HU, Hangzhou (CN); JINGTAO XU, Linfen (CN); HANGFU YANG, Hangzhou (CN); QIONG WU, Hangzhou (CN); JIAGE JIA, Lingbao (CN); MINXIANG PAN, Hangzhou (CN); SHENGKAI ZHOU, Qujing (CN); HAOJIN YE, Deyang (CN)

(21) Appl. No.: 19/707,070

(22) Filed: Jun. 12, 2026

(51) Int. Cl. G01R 33/02; G01R 35/00

(52) U.S. Cl. CPC G01R 33/02; G01R 35/005

(57) ABSTRACT

The present invention provides a magnetic field microprobe based on an anomalous Nernst effect and a calibration and application method therefor; the magnetic field microprobe includes a magnetic field sensing unit, a laser heating unit, a microprobe support structure, and a voltage detection and processing unit. The magnetic field sensing unit includes a substrate, an annular or nearly annular magnetic thin-film microstructure, and a voltage electrode; the laser heating unit heats a heated center of the magnetic thin-film microstructure to form a radial temperature gradient; and the voltage detection and processing unit acquires an anomalous Nernst voltage and obtain information of a magnetic field to be measured. According to the present invention, it does not need an additional bias magnetic field and an electric heating source, and has the advantages of low power consumption, high linearity, adjustable sensitivity, and suitability for miniaturized applications.

### TECHNICAL FIELD

The present invention relates to the field of magnetic field sensing technology, and specifically relates to a magnetic field microprobe based on an anomalous Nernst effect and a calibration and application method therefor.

### BACKGROUND

Magnetic field measurement technology is widely used in the fields of current detection, magnetic material characterization, chip-level magnetic sensing, geomagnetic detection, biomagnetic signal detection, micro-nano scale electromagnetic field distribution analysis, and the like. With electronic apparatuses, microelectromechanical systems, and integrated detection devices continuously developing to meet miniaturization, low power consumption, and high spatial resolution, the limitations gradually occurs on traditional magnetic field sensors in micro-scale local magnetic field detection, especially in application scenarios requiring proximity to a surface of a sample to be measured, measuring magnetic fields with non-uniformly distributed space, or implementing chip-level integration, more requirements are proposed for the size, sensitivity, linearity, power consumption, and anti-interference performance of the magnetic field sensors.

The currently common magnetic field sensors mainly include Hall sensors, magnetoresistive sensors, and superconducting quantum interference apparatuses. The Hall sensors have a relatively mature structure, but are usually large in active detection regions, making it difficult to meet spatial resolution requirements for micro-scale local magnetic field measurement; moreover, for the Hall sensors, it is usually needed to charge a drive current, but the drive current will cause problems such as Joule heat, electrical noise, and increased power consumption, resulting in influences on measurement accuracy in measurement scenarios with small size, low power consumption, or high stability. The magnetoresistive sensors have high sensitivity, but it is usually needed to establish a linear response region through an additional bias magnetic field or a specific magnetization structure, consequently, the apparatus structure and debugging methods are relatively complex, and the hysteresis effect inherent in magnetic materials may degrade the repeatability of output signals, resulting in influence on the accuracy of quantitative magnetic field detection. The superconducting quantum interference apparatuses have extremely high magnetic field detection sensitivity, but they are generally operated in a low-temperature environment, resulting in high system costs and large size, so it is difficult to directly apply the superconducting quantum interference apparatuses to portable devices, microprobes, or ordinary chip-level detection systems.

An anomalous Nernst effect is a physical effect by which a transverse voltage will be generated based on coupling between a temperature gradient and magnetization intensity in the magnetic material. If there is the temperature gradient in the magnetic material and the material has a certain magnetization intensity, a voltage signal can be formed in a direction perpendicular to both a temperature gradient direction and a magnetization direction. Since this voltage signal corresponds to a magnetization status of the magnetic material, it can be used for magnetic field detection. Compared with drive-current-based Hall effect or magnetoresistance effect type detection methods, the anomalous Nernst effect theoretically has the potential for low power consumption, electromagnetic interference resistance, and easy miniaturization, so it is suitable for building magnetic field sensing structures for measuring micro-scale magnetic fields.

However, existing anomalous Nernst effect based magnetic field detection solutions still have several shortcomings. 1, in the anomalous Nernst effect, it is needed to establish a stable temperature gradient in the magnetic material; in traditional solutions, a resistive heating way is usually carried out to achieve the temperature gradient, but in micron-scale apparatuses, an electrical heating structure requires additional heating wires, insulating layers, and lead structures, which not only increases apparatus structural complexity but also easily causes problems such as electromagnetic crosstalk, Joule heat accumulation, and degradation in reliability of the heating wires. 2, in micro-scale structures, it is difficult to achieve a high and stable local temperature gradient by the resistive heating way, and it is difficult to precisely control a direction and a magnitude of the temperature gradient, resulting in influence on stable output of the anomalous Nernst voltage. 3, if existing magnetic thin-film sensor structures cannot achieve a good linear magnetization response within the range of a magnetic field to be measured, it is difficult to establish a stable linear conversion relationship between the anomalous Nernst voltage and the magnetic field, which is unfavorable for quantitative measurement. 4, if the apparatuses require the additional bias magnetic field to establish a linear operating range, it will increase the complexity of a testing system and limit the application in portable, low-power-consumption, and chip-level scenarios.

Therefore, it is urgently needed to provide a novel magnetic field microprobe structure, which can achieve a stable and tunable temperature gradient in a micro-scale magnetic thin film structure, and enable a magnetic thin film to achieve a good linear magnetization response in a perpendicular additional magnetic field, thereby realizing high-linear and low-power-consumption detection on the micro-scale local magnetic fields without the additional bias magnetic field or an electric heating source.

### SUMMARY

In order to solve the above problems, the present invention provides a magnetic field microprobe based on an anomalous Nernst effect and a calibration and use method therefor, which can effectively solve the shortcomings in the prior art.

The present invention is implemented by the following technical solution: the magnetic field microprobe based on the anomalous Nernst effect includes a magnetic field sensing unit, a laser heating unit, a microprobe support structure, and a voltage detection and processing unit; the magnetic field sensing unit includes a substrate, a magnetic thin-film microstructure arranged on the substrate, and a voltage electrode electrically connected to the magnetic thin-film microstructure; the magnetic thin-film microstructure is an annular or nearly annular microstructure extending around a heated center; the magnetic thin-film microstructure has a direction of easy magnetization perpendicular to a film plane and can achieve a net magnetization intensity by an external magnetic field perpendicular to the film plane, and the net magnetization intensity varies with the external magnetic field; the laser heating unit is positioned relative to the magnetic field sensing unit through the microprobe support structure, and a light output direction of the laser heating unit faces the heated center of the magnetic thin-film microstructure so as to form a radial temperature gradient that diffuses outward from the heated center within a plane with the magnetic thin-film microstructure; and the voltage detection and processing unit is configured to acquire an anomalous Nernst voltage generated by the magnetic thin-film microstructure under the cooperation of the radial temperature gradient and the net magnetization intensity through the voltage electrode, and then to obtain information of the magnetic field to be measured based on the anomalous Nernst voltage.

As a preferred technical solution, the magnetic thin-film microstructure has a multi-domain structure with staggered magnetization directions in a zero magnetic field status; under the influence of the external magnetic field, a magnetic domain region in a direction consistent with the external magnetic field and a magnetic domain region in a direction opposite to the external magnetic field are subjected to changes in area through reversible displacement of domain walls, and therefore, the net magnetization intensity of the magnetic thin-film microstructure is in a linear or approximately linear relationship with the external magnetic field perpendicular to the film plane within a preset measurement range.

As a preferred technical solution, the magnetic thin-film microstructure is composed of a single-layer or multilayer thin film formed by ferromagnetic metal materials, magnetic topological materials, or a combination thereof; and the magnetic thin-film microstructure is formed on the substrate by deposition, sputtering, etching, or patterning processes, and a thickness of the magnetic thin-film microstructure is less than or equal to 100 nm.

As a preferred technical solution, the magnetic thin-film microstructure is an annular thin-film microstructure with an opening; the voltage electrode includes a first voltage electrode and a second voltage electrode which are respectively connected to both sides of the opening; the first voltage electrode and the second voltage electrode are respectively connected to the voltage detection and processing unit, and the anomalous Nernst voltage generated in a circumferential direction of the annular thin-film microstructure can be outputted by the first voltage electrode and the second voltage electrode.

As a preferred technical solution, a ring width of the annular thin-film microstructure is less than or equal to 5 μm, and an outer diameter is less than or equal to 10 μm; a laser spot formed by the laser heating unit is in a central region of the annular thin-film microstructure, and heat flows are distributed in a radial direction of the annular thin-film microstructure.

As a preferred technical solution, the substrate is a silicon-containing substrate, a silicon oxide substrate, an insulating substrate, or a composite substrate; a thermal isolation structure is arranged below the substrate and corresponds to the magnetic thin-film microstructure; and the thermal isolation structure includes at least one of a suspended film, a back cavity, a groove, or a thinned region, and is configured to reduce the heat dissipation of the magnetic thin-film microstructure toward the substrate and enhance the radial temperature gradient.

As a preferred technical solution, the laser heating unit includes a laser light source, a spot size controller, and a heating power controller; the spot size controller is configured to adjust a size of the laser spot irradiated on the magnetic thin-film microstructure; the heating power controller is configured to adjust a laser output power to change a magnitude of the radial temperature gradient and adjust a magnetic field sensitivity of the magnetic microprobe; the microprobe support structure includes a sensor end fixing part for fixing the magnetic field sensing unit, and a light source fixing part for fixing or limiting the laser heating unit; an optical path alignment space is formed between the sensor end fixing part and the light source fixing part, and a spot center of the laser heating unit is coaxial or approximately coaxial with the heated center of the magnetic thin-film microstructure; and the microprobe support structure is also provided with a lead channel for leading out leads of the voltage electrode.

A calibration and application method for a magnetic field microprobe based on an anomalous Nernst effect provided by the present invention includes the following steps:
step 1: placing the magnetic field microprobe in a standard uniform magnetic field generation apparatus, and making a direction of a standard uniform magnetic field generated by the standard uniform magnetic field generation apparatus perpendicular to the film plane of the magnetic thin-film microstructure;
step 2: activating the laser heating unit, and adjusting the spot size and heating power of the laser heating unit to form a stable radial temperature gradient in the plane with the magnetic thin-film microstructure;
step 3: adjusting a magnetic field value of the standard uniform magnetic field generation apparatus within a predetermined calibration range, and recording the anomalous Nernst voltage outputted by the magnetic field sensing unit under different magnetic field values through the voltage detection and processing unit;
step 4: performing linear fitting based on a correspondence relationship between the anomalous Nernst voltage and the standard uniform magnetic field to obtain a magnetic field sensitivity coefficient of the magnetic field microprobe; and
step 5: placing the calibrated magnetic field microprobe on a surface of a sample to be measured or a position of a space to be measured, acquiring the anomalous Nernst voltage under a to-be-measured status through the voltage detection and processing unit, and obtaining the intensity of the magnetic field to be measured in combination with the magnetic field sensitivity coefficient.

As a preferred technical solution, in step 2, the laser heating unit is utilized to irradiate and heat the central region of the magnetic thin-film microstructure, and the heat flows are diffused along the radial direction of the magnetic thin-film microstructure, and thus the magnetic thin-film microstructure generates the anomalous Nernst voltage accumulated along an annular path by the radial temperature gradient in combination with the net magnetization perpendicular to the film plane.

As a preferred technical solution, between step 2 and step 4, the spot size and/or heating power of the laser heating unit are/is changed so as to adjust the magnitude of the radial temperature gradient in the plane with the magnetic thin-film microstructure, and moreover, the corresponding magnetic field sensitivity coefficient is re-obtained, thus the magnetic field microprobe under different sensitivity conditions can be applied to magnetic field measurement on magnet surfaces, non-contact current measurement, geomagnetic detection, biomagnetic imaging, or electronic compasses.

The present invention has the following beneficial effects: 1, in the present invention, the laser heating unit is utilized to irradiate and heat the central region of the magnetic thin-film microstructure so as to form the radial temperature gradient that diffuses outward from the center within the plane with the magnetic thin-film microstructure, it does not require additional resistance heating wires fabricated in the microprobe, so that the Joule heat, electrical noise, and electromagnetic interference problems caused by an electric heating structure can be reduced, thereby helping reduce apparatus power consumption and improve signal stability.

2, in the present invention, the magnetic thin-film microstructure is arranged to be the annular or nearly annular microstructure, and a corresponding relationship is kept between the laser spot and the heated center of the magnetic thin-film microstructure, such that the temperature gradient can be distributed in the radial direction of the annular structure, the anomalous Nernst voltage can be generated and accumulatively outputted along the annular path, thereby improving the output signal strength and enhancing the response of the magnetic field microprobe to weak changes in the magnetic field.

3, the magnetic thin-film microstructure in the present invention has a direction of easy magnetization perpendicular to the film plane and can form the multi-domain structure in the zero magnetic field condition; and by changing an area ratio of different magnetic domain regions through reversible displacement of the domain wall under the influence of the external magnetic field, the net magnetization intensity can vary with the external magnetic field to achieve the linear or approximately linear relationship, thus a good linear correspondence relationship can be formed between the anomalous Nernst voltage and the magnetic field to be measured, which is beneficial for quantitative detection of the magnetic field.

4, in the present invention, the magnetic field microprobe can establish a measurement response relationship without the additional bias magnetic field, thus the testing system structure is simplified, the requirements for application conditions are decreased, and the applicability of the microprobe in portable magnetic field detection, chip-level magnetic sensing, and non-contact current monitoring scenarios is improved.

5, in the present invention, by adjusting the size of the laser spot and heating power, the amplitude of the radial temperature gradient in the magnetic thin-film microstructure can be changed, thus the magnetic field sensitivity of the magnetic field microprobe can be adjusted to achieve sensitivity matching of the same magnetic field microprobe in different measurement scenarios, thereby improving application flexibility.

6, in the present invention, the magnetic field sensing unit can be prepared by micro-nano machining processes such as thin-film deposition and patterned etching, and the structural size can be reduced at the micron level, making it compatible with chip-level processes; it can be applied to local magnetic field measurement with micro-scale spatial resolution, especially suitable for detecting surface magnetic field distribution of the sample to be measured, micro-current magnetic field distribution, and small magnetic apparatuses.

### BRIEF DESCRIPTION OF THE DRAWINGS

In order to more clearly illustrate the technical solutions of the embodiments of the present invention or the prior art, the accompanying drawings used in the description of the embodiments or the prior art will be briefly introduced below. Obviously, the following described accompanying drawings are only some embodiments of the present invention, and for those of ordinary skill in the art, other drawings can be obtained based on these accompanying drawings without any creative effort.

FIG. 1 is a schematic diagram of overall composition of a magnetic microprobe testing device based on an anomalous Nernst effect according to the present invention;

FIG. 2 is a sectional schematic structural diagram of a magnetic microprobe according to the present invention;

FIG. 3 is a schematic diagram of a working principle of magnetic field detection by a magnetic microprobe based on an anomalous Nernst effect according to the present invention;

FIG. 4 is a curve chart of a linear relationship between an anomalous Nernst voltage and a magnetic field intensity of a magnetic microprobe under different laser heating power conditions according to the present invention;

FIG. 5 is a schematic diagram of an application status of a magnetic microprobe in measuring a surface magnetic field of a sample to be measured according to the present invention; and

FIG. 6 is a schematic diagram of magnetic field distribution results of a magnetic microprobe measuring a surface magnetic field of a sample to be measured according to the present invention.

Reference numerals: 1, substrate; 2, magnetic thin-film microstructure; 3, laser heating unit; 4, voltage detection and processing unit; 5, microprobe support structure; 6, voltage electrode; 7, magnetic field sensing unit; 8, magnetic field microprobe; and 9, uniform magnetic field generation apparatus.

### DESCRIPTION OF EMBODIMENTS

All features disclosed in this specification, or all steps in methods or processes disclosed, except for mutually exclusive features and/or steps, can be combined in any way.

Any feature disclosed in this specification (including any additional claims, abstracts, and accompanying drawings) can be replaced by other equivalent or similar alternative features, unless otherwise specified. That is, unless otherwise specified, each feature is just one example in a series of equivalent or similar features.

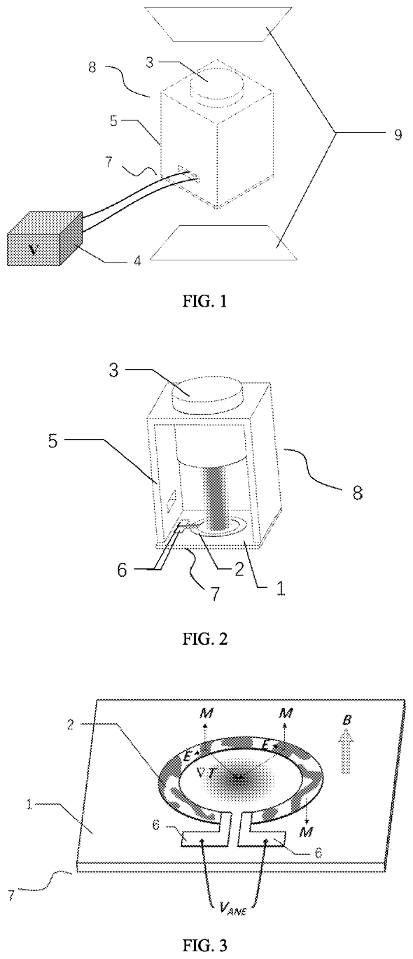

According to the present invention, in specific implementation, as shown in FIG. 1 to FIG. 6, a magnetic field microprobe 8 based on an anomalous Nernst effect includes a magnetic field sensing unit 7, a laser heating unit 3, a microprobe support structure 5, and a voltage detection and processing unit 4. The magnetic field sensing unit 7, serving as a core part for magnetic sensing and anomalous Nernst voltage generation, includes a substrate 1, a magnetic thin-film microstructure 2 arranged on the substrate 1, and a voltage electrode 6 electrically connected to the magnetic thin-film microstructure 2. The substrate 1 is configured to bear the magnetic thin-film microstructure 2 and provides a stable micro-nano processing support surface for the magnetic thin-film microstructure 2, so that the magnetic thin-film microstructure 2 can be formed on the substrate 1 in a form of a predetermined pattern. The magnetic thin-film microstructure 2 is an annular or nearly annular microstructure extending around the heated center; and by means of the annular or nearly annular structure, heat flows generated after laser heating can be diffused uniformly from the heated center to a circumferential outer side of the annular structure, thus forming a stable radial temperature gradient within a plane with the magnetic thin-film microstructure 2. The magnetic thin-film microstructure 2 has a direction of easy magnetization perpendicular to the film plane; and under the influence of an external magnetic field perpendicular to the film plane, the net magnetization intensity of the magnetic thin-film microstructure 2 can vary with the external magnetic field, thereby providing a magnetization basis for generating the anomalous Nernst voltage.

The magnetic thin-film microstructure 2 in the magnetic field sensing unit 7 has a multi-domain structure with staggered magnetization directions in a zero magnetic field condition, the magnetization direction of each magnetic domain is opposite or different along a normal direction of a film layer, thus the overall net magnetization intensity is small or close to zero near a zero magnetic field. If the external magnetic field perpendicular to the film plane is applied to the magnetic thin-film microstructure 2, the magnetic domain region in a direction consistent with the external magnetic field gradually expands through reversible displacement of the domain wall, while a magnetic domain region in a direction opposite to the external magnetic field shrinks correspondingly, thereby generating the net magnetization intensity along the external magnetic field direction by the magnetic thin-film microstructure 2. Since the changes in magnetic domain area mainly rely on the reversible displacement of the domain wall, the net magnetization intensity of the magnetic thin-film microstructure 2 can be subjected to linear or nearly linear variation with the external magnetic field within the predetermined measurement range, thus a correspondence relationship that can be used for quantitative measurement is formed between the anomalous Nernst voltage outputted by the magnetic field microprobe 8 and the magnetic field to be measured.

The magnetic thin-film microstructure 2 can be made from ferromagnetic metal materials, magnetic topological materials, or a combination thereof, or it can be a single-layer or multilayer thin-film structure. The magnetic thin-film microstructure 2 can be formed on substrate 1 by micro-nano machining processes such as deposition, sputtering, etching, and photolithography patterning, and thus it has a micro-level pattern size and a stable thin-film structure. In order to ensure that the magnetic thin-film microstructure 2 has good miniaturization capability and thermal response capability, a thickness of the magnetic thin-film microstructure 2 is preferably set to less than or equal to 100 nm, such that the magnetic thin-film microstructure can maintain perpendicular magnetic anisotropy, and can also quickly establish the temperature gradient under laser heating conditions and generate an effective anomalous Nernst voltage.

In a preferred embodiment, the magnetic thin-film microstructure 2 is arranged as an annular thin-film microstructure with an opening, and the voltage electrode 6 includes a first voltage electrode and a second voltage electrode which are respectively connected to both sides of the opening. The first voltage electrode and the second voltage electrode are respectively lead out from ends of the opening of the annular thin-film microstructure and are electrically connected to the voltage detection and processing unit 4. Because the laser heating unit 3 irradiates and heats the central region of the annular thin-film microstructure, the heat flows can be diffused outward from the central region along a radial direction of the annular structure; the magnetization direction of the magnetic thin-film microstructure 2 is perpendicular to the film plane, and by means of the cooperation of the radial temperature gradient and the perpendicular magnetization intensity, the annular thin-film microstructure generates the anomalous Nernst voltage along the annular path. After being accumulated along the annular path, the anomalous Nernst voltage is outputted by the first voltage electrode and the second voltage electrode, thereby enhancing the voltage signal strength and improving the response capability of the magnetic field microprobe 8 to weak changes in the magnetic field.

In order to further improve the detection capability of micro-scale magnetic fields, a ring width of the annular thin-film microstructure is preferably set to be less than or equal to 5 μm, and an outer diameter is preferably set to be less than or equal to 10 μm. The magnetic thin-film microstructure 2 with these dimensions can form small sensing regions for detecting local magnetic fields on the surface of samples to be tested or micro-space magnetic fields. A laser spot formed by the laser heating unit 3 is in the central region of the annular thin-film microstructure, and the center of the laser spot is coaxial or nearly coaxial with the center of the annular thin-film microstructure, so that the heated center corresponds to a geometric center of the annular structure. Therefore, the temperature generated after laser heating is distributed more uniformly, the heat flows are mainly distributed along the radial direction of the annular thin-film microstructure, thereby reducing signal errors caused by asymmetric heating.

The substrate 1 can be a silicon-containing substrate, a silicon oxide substrate, an insulating substrate, or a composite substrate. In order to enhance the radial temperature gradient formed by the laser heating unit 3 in a region with the magnetic thin-film microstructure 2, a thermal isolation structure is arranged below the substrate 1 and corresponds to the magnetic thin-film microstructure 2. The thermal isolation structure can be at least one of a suspended film, a back cavity, a groove, or a thinned region. If the suspended film or the back cavity is formed below the magnetic thin-film microstructure 2, the loss in thermal conductivity from the magnetic thin-film microstructure 2 to the substrate 1 is decreased, thus it is easier for a laser input energy to form a large temperature gradient within the plane with the magnetic thin-film microstructure 2, thereby increasing an output amplitude of the anomalous Nernst voltage. This thermal isolation structure can also improve a thermal response speed of the magnetic field microprobe 8, so that the magnetic field sensing unit 7 can quickly reach a stable measurement status when the laser heating power changes.

The laser heating unit 3 is configured to provide a non-contact heating energy to the magnetic thin-film microstructure 2 and includes a laser light source, a spot size controller, and a heating power controller. A laser beam emitted by the laser source irradiates the heated center of the magnetic thin-film microstructure 2; the spot size controller is configured to adjust the laser spot size to match laser spot with the central region of the annular thin-film microstructure, thereby preventing the spot from being too large to cause the heating region to diffuse to the voltage electrode 6 or other non-target regions, as well as preventing the spot from being too small to cause local overheating. The heating power controller is configured to adjust the laser output power to change the amplitude of the radial temperature gradient in the plane with the magnetic thin-film microstructure 2. If the laser power increases, the temperature gradient amplitude in the magnetic thin-film microstructure 2 rises accordingly, the anomalous Nernst voltage output increases, and the magnetic field sensitivity of the magnetic field microprobe 8 correspondingly increases; and if the laser power decreases, the temperature gradient amplitude decreases, and thus the magnetic field microprobe 8 can operate under lower thermal load conditions. By means of coordinated adjustment on the spot size and the laser power, the magnetic field microprobe 8 can be adapted to test scenarios with different magnetic field intensity ranges and sensitivity requirements.

The microprobe support structure 5 is configured to maintain a spatial positional relationship between the magnetic field sensing unit 7 and the laser heating unit 3, and to ensure that the laser spot can accurately irradiate the heated center of the magnetic thin-film microstructure 2. The microprobe support structure 5 includes a sensor end fixing part for fixing the magnetic field sensing unit 7 and a light source fixing part for fixing or limiting the laser heating unit 3, and a light path alignment space is formed between the sensor end fixing part and the light source fixing part, so that a light output direction of the laser heating unit 3 can face the magnetic thin-film microstructure 2. During specific assembling of the microprobe support structure 5, an optical axis of the laser source is coaxial or approximately coaxial with the heated center of the magnetic thin-film microstructure 2, thereby ensuring the symmetry of the radial temperature gradient. The microprobe support structure 5 is also provided with a lead channel for leading out leads of the voltage electrode 6, such that the voltage electrode 6 can be stably connected to the external voltage detection and processing unit 4, thereby avoiding the leads from blocking the laser path or affecting the magnetic field sensing unit 7 near the surface of the sample to be measured.

The voltage detection and processing unit 4 is connected to the voltage electrode 6 by the leads and is configured to acquire the anomalous Nernst voltage generated by the magnetic field sensing unit 7. Since the anomalous Nernst voltage is usually a weak voltage signal, the voltage detection and processing unit 4 can include a low-noise voltage acquisition part, a signal amplification part, a filtering and denoising part, and a data processing part. The low-noise voltage acquisition part is configured to acquire a voltage difference between the first voltage electrode and the second voltage electrode, the signal amplification part is configured to increase the amplitude of the weak voltage signal, the filtering and denoising part is configured to attenuate external noise and system interference, and the data processing part is configured to convert the magnetic field to be measured according to the preset magnetic field sensitivity coefficient obtained through prior calibration. By means of above processing, the magnetic field microprobe 8 can convert the magnetization changes in the magnetic thin-film microstructure 2 into a readable voltage signal, and further convert it into the information of thee magnetic field to be measured.

Before using the magnetic field microprobe 8, it is needed to perform calibration. During calibration, the magnetic field microprobe 8 is placed in the standard uniform magnetic field generation apparatus 9, and the direction of the standard uniform magnetic field generated by the standard uniform magnetic field generation apparatus 9 is perpendicular to the film plane of the magnetic thin-film microstructure 2. Then, the laser heating unit 3 is activated, and the size of the laser spot and the heating power are adjusted so that the stable radial temperature gradient is formed in the plane with the magnetic thin-film microstructure 2. After the radial temperature gradient stabilizes, the magnetic field value of the standard uniform magnetic field generation apparatus 9 is adjusted within the predetermined calibration range, thus the standard uniform magnetic field can gradually change from a negative set magnetic field to a positive set magnetic field, or can change the magnetic field intensity point by point at predetermined intervals. At each magnetic field value, the voltage detection and processing unit 4 records the anomalous Nernst voltage outputted by the magnetic field sensing unit 7. After acquiring a set of magnetic field values and voltage values, linear fitting is performed based on the correspondence relationship between anomalous Nernst voltage and the standard uniform magnetic field, and a slope of a fitting curve is treated as the magnetic field sensitivity coefficient of the magnetic field microprobe 8 under the current laser heating conditions. After calibration, the magnetic field microprobe 8 is placed on the surface of the sample to be measured or in the position of the space to be measured. The anomalous Nernst voltage under the to-be-measured status is acquired by the voltage detection and processing unit 4, and then it is converted in combination with the magnetic field sensitivity coefficient to obtain the intensity of the magnetic field to be measured.

During actual measurement, the laser heating unit 3 irradiates and heats the central region of the magnetic thin-film microstructure 2, the heat flows are diffused along the radial direction of the magnetic thin-film microstructure 2, and the magnetic thin-film microstructure 2 generates the anomalous Nernst voltage under the cooperation influence of the radial temperature gradient and the net magnetization intensity perpendicular to the film plane. Because the annular thin-film microstructure has the annular path, the locally generated anomalous Nernst voltage can be accumulated along the annular path and be outputted by the voltage electrode 6; compared to an ordinary linear thin-film structure, the magnetic field sensing unit 7 in the present invention can achieve a stronger voltage output. By changing the spot size and heating power of the laser heating unit 3, the radial temperature gradient amplitude within the plane with the magnetic thin-film microstructure 2 can be adjusted, and the corresponding magnetic field sensitivity coefficient can be obtained again, so that the same magnetic field microprobe 8 under different sensitivity conditions can be applied to application scenarios such as magnetic field measurement on the magnet surfaces, non-contact current measurement, geomagnetic detection, biomagnetic imaging, and electronic compasses.

In a specific preparation and testing process, a Co/Ru/Pt multilayer film having perpendicular magnetic anisotropy can be selected as a material of the magnetic thin-film microstructure 2, the overall thickness of the multilayer film is 50 nm, and it is formed on a Si/SiO₂ substrate 1 by deposition. Then, the multilayer film is processed into an open annular pattern by etching or patterning processes, and the ring has an inner diameter of 6 μm, an outer diameter of 8 μm, and a width of the opening is 1.5 μm. In order to achieve the output of the anomalous Nernst voltage, Au electrodes with a thickness of 80 nm are deposited at both ends of an annular opening as the voltage electrodes 6, the voltage electrodes 6 are respectively connected to both sides of the opening of the annular magnetic thin-film microstructure 2. In order to reduce heat dissipation to the substrate 1, a suspended silicon film with a thickness of 1 μm can be fabricated below the ring by etching, thus the magnetic thin-film microstructure 2 can achieve a higher radial temperature gradient under laser heating conditions.

After the above structure is fabricated, the laser heating unit 3 is activated, the laser spot diameter is adjusted to be 4 μm, and the laser power is set to be 20 mW, so that the laser spot irradiates the central region of the annular magnetic thin-film microstructure 2, and a stable temperature gradient diffusing outward from the center is formed in the ring. Then, the magnetic field microprobe 8 is placed in the perpendicular magnetic field generation apparatus, and the external magnetic field direction is perpendicular to the film plane of the magnetic thin-film microstructure 2. The magnetic thin-film microstructure 2 forms a black-and-white domain structure in the zero magnetic field status, at the moment, the contributions of domains with different directions to the overall net magnetization cancel each other out, resulting in a voltage value of 0 at both ends of the voltage electrode 6. As the external magnetic field gradually increases, the domain area with the same direction as the external magnetic field gradually increases, and the area of the domain in the direction opposite to the external magnetic field gradually decreases. As shown in FIG. 3, the net magnetization intensity in the magnetic thin-film microstructure 2 gradually increases along with the increase of the external magnetic field, and the anomalous Nernst voltage outputted from both ends of the voltage electrode 6 increases linearly with the magnetic field. As the external magnetic field decreases to 0, the voltage correspondingly decreases to 0; once the magnetic field is reversely increased, the net magnetization direction of the magnetic thin-film microstructure 2 changes correspondingly, and negative voltage is outputted from both ends of the voltage electrode 6, with absolute values gradually increased with the reverse magnetic field.

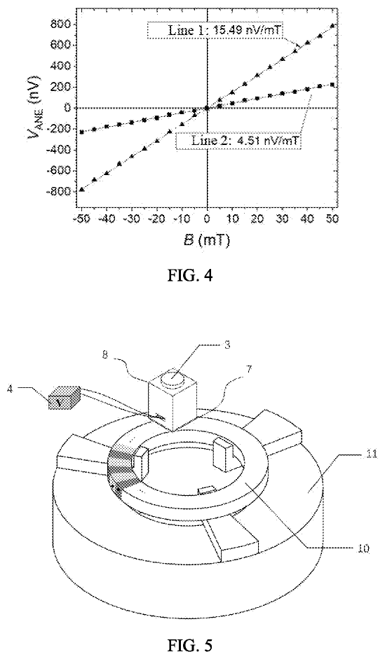

If the laser power is 20 mW, linear fitting is performed on the relationship between the anomalous Nernst voltage and the magnetic field intensity acquired by the voltage detection and processing unit 4, thus the linear relationship shown as Line 1 in FIG. 4 can be obtained, and the magnetic field sensitivity coefficient of the magnetic microprobe 8 is calculated as 4.51 nV/mT based on the slope of the linear fitting. Then, the heating power controller in the laser heating unit 3 is adjusted to increase the laser power to be 60 mW; under the condition that other test conditions are kept consistent, the relationship between the anomalous Nernst voltage and the magnetic field intensity is re-acquired to obtain a linear relationship shown as Line 2 in FIG. 4, and at the moment, the magnetic field sensitivity coefficient increases to 15.49 nV/mT. This indicates that the sensitivity of the magnetic field microprobe 8 can be controlled by adjusting the laser heating power, and good linear magnetic field response can be kept under different laser heating power levels.

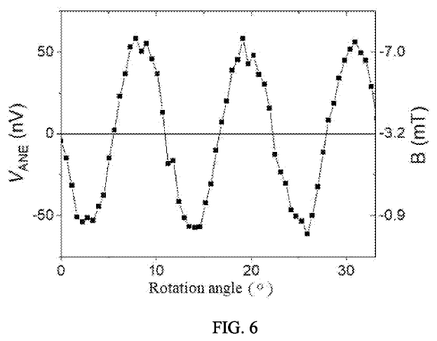

After calibration, the magnetic field microprobe 8 can be configured to measure the surface magnetic field distribution of the sample to be measured. Specifically, the calibrated magnetic field microprobe 8 is placed above the sample to be measured, as shown in FIG. 5, and the laser power is set to be 20 mW to maintain the stable radial temperature gradient for the magnetic thin-film microstructure 2. The sample to be measured can be a sample with periodic magnetizing poles, and a magnetic field that varies periodically is formed in space. The sample to be measured is placed on a rotary stage, and the rotary stage is driven to rotate the sample to be measured, so as to make different positions on the surface of the sample to be measured pass sequentially through a detection region of the magnetic field microprobe 8. The voltage detection and processing unit 4 continuously records the voltage values outputted by the magnetic field microprobe 8 from different positions, and converts the voltage values into the corresponding magnetic field intensity based on the pre-obtained magnetic field sensitivity coefficient, thereby obtaining the magnetic field distribution on the surface of the sample to be measured, as shown in FIG. 6. This measurement process demonstrates that the magnetic field microprobe 8 in the present invention can perform local magnetic field measurement within the micro-scale sensing region, and has the characteristics of simple structure, low power consumption, no need of additional bias magnetic fields, adjustable sensitivity, and suitability for miniaturized applications.

The above is just a specific embodiment of the present invention, but the protection scope of the present invention is not limited to this. Any changes or substitutions that can be thought of without creative effort should be covered within the protection scope of the present invention. Therefore, the protection scope of the present invention should be based on the scope defined in the claims.

What is claimed is:

1. A magnetic field microprobe based on an anomalous Nernst effect, comprising a magnetic field sensing unit, a laser heating unit, a microprobe support structure, and a voltage detection and processing unit, wherein
the magnetic field sensing unit comprises a substrate, a magnetic thin-film microstructure arranged on the substrate, and a voltage electrode electrically connected to the magnetic thin-film microstructure; the magnetic thin-film microstructure is an annular or nearly annular microstructure extending around a heated center; the magnetic thin-film microstructure has a direction of easy magnetization perpendicular to a film plane and is capable of achieve a net magnetization intensity by an external magnetic field perpendicular to the film plane, and the net magnetization intensity varies with the external magnetic field;
the laser heating unit is positioned relative to the magnetic field sensing unit through the microprobe support structure, and a light output direction of the laser heating unit faces the heated center of the magnetic thin-film microstructure so as to form a radial temperature gradient that diffuses outward from the heated center within a plane with the magnetic thin-film microstructure;
the voltage detection and processing unit is configured to acquire an anomalous Nernst voltage generated by the magnetic thin-film microstructure under the cooperation of the radial temperature gradient and the net magnetization intensity through the voltage electrode, and then to obtain information of the magnetic field to be measured based on the anomalous Nernst voltage.

2. The magnetic field microprobe based on the anomalous Nernst effect according to claim 1, wherein the magnetic thin-film microstructure has a multi-domain structure with staggered magnetization directions in a zero magnetic field status; under the influence of the external magnetic field, a magnetic domain region in a direction consistent with the external magnetic field and a magnetic domain region in a direction opposite to the external magnetic field are subjected to changes in area through reversible displacement of a domain wall, and then the net magnetization intensity of the magnetic thin-film microstructure is in a linear or approximately linear relationship with the external magnetic field perpendicular to the film plane within a predetermined measurement range.

3. The magnetic field microprobe based on the anomalous Nernst effect according to claim 1, wherein the magnetic thin-film microstructure is composed of a single-layer or multilayer thin film formed by ferromagnetic metal materials, magnetic topological materials, or a combination thereof; and the magnetic thin-film microstructure is formed on the substrate by deposition, sputtering, etching, or patterning processes, and a thickness of the magnetic thin-film microstructure is less than or equal to 100 nm.

4. The magnetic field microprobe based on the anomalous Nernst effect according to claim 1, wherein the magnetic thin-film microstructure is an annular thin-film microstructure with an opening; the voltage electrode comprises a first voltage electrode and a second voltage electrode which are respectively connected to both sides of the opening; and the first voltage electrode and the second voltage electrode are respectively connected to the voltage detection and processing unit, and the anomalous Nernst voltage generated in a circumferential direction of the annular thin-film microstructure is outputted by the first voltage electrode and the second voltage electrode.

5. The magnetic field microprobe based on the anomalous Nernst effect according to claim 4, wherein a ring width of the annular thin-film microstructure is less than or equal to 5 μm, and an outer diameter is less than or equal to 10 μm; and a laser spot formed by the laser heating unit is in a central region of the annular thin-film microstructure, and heat flows are distributed in a radial direction of the annular thin-film microstructure.

6. The magnetic field microprobe based on the anomalous Nernst effect according to claim 1, wherein the substrate is a silicon-containing substrate, a silicon oxide substrate, an insulating substrate, or a composite substrate; a thermal isolation structure is arranged below the substrate and corresponds to the magnetic thin-film microstructure; and the thermal isolation structure comprises at least one of a suspended film, a back cavity, a groove, or a thinned region, and is configured to reduce the heat dissipation of the magnetic thin-film microstructure toward the substrate and enhance the radial temperature gradient.

7. The magnetic field microprobe based on the anomalous Nernst effect according to claim 1, wherein the laser heating unit comprises a laser light source, a spot size controller, and a heating power controller; the spot size controller is configured to adjust a size of the laser spot irradiated on the magnetic thin-film microstructure; the heating power controller is configured to adjust a laser output power to change a magnitude of the radial temperature gradient and adjust a magnetic field sensitivity of the magnetic microprobe; the microprobe support structure comprises a sensor end fixing part for fixing the magnetic field sensing unit, and a light source fixing part for fixing or limiting the laser heating unit; an optical path alignment space is formed between the sensor end fixing part and the light source fixing part, and then a spot center of the laser heating unit is coaxial or approximately coaxial with the heated center of the magnetic thin-film microstructure; and the microprobe support structure is also provided with a lead channel for leading out leads of the voltage electrode.

8. A calibration and application method for the magnetic field microprobe based on the anomalous Nernst effect according to claim 1, comprising the following steps:
step 1: placing the magnetic field microprobe in a standard uniform magnetic field generation apparatus, and making a direction of a standard uniform magnetic field generated by the standard uniform magnetic field generation apparatus perpendicular to the film plane of the magnetic thin-film microstructure;
step 2: activating the laser heating unit, and adjusting the spot size and heating power of the laser heating unit to form a stable radial temperature gradient in the plane with the magnetic thin-film microstructure;
step 3: adjusting a magnetic field value of the standard uniform magnetic field generation apparatus within a predetermined calibration range, and recording the anomalous Nernst voltage outputted by the magnetic field sensing unit under different magnetic field values through the voltage detection and processing unit;
step 4: performing linear fitting based on a correspondence relationship between the anomalous Nernst voltage and the standard uniform magnetic field to obtain a magnetic field sensitivity coefficient of the magnetic field microprobe; and
step 5: placing the calibrated magnetic field microprobe on a surface of a sample to be measured or a position of a space to be measured, acquiring the anomalous Nernst voltage under a to-be-measured status through the voltage detection and processing unit, and obtaining the intensity of the magnetic field to be measured in combination with the magnetic field sensitivity coefficient.

9. The calibration and use method according to claim 8, wherein in step 2, the laser heating unit is utilized to irradiate and heat the central region of the magnetic thin-film microstructure, the heat flows are diffused along the radial direction of the magnetic thin-film microstructure, and the magnetic thin-film microstructure generates the anomalous Nernst voltage accumulated along an annular path by the radial temperature gradient in combination with the net magnetization perpendicular to the film plane.

10. The calibration and use method according to claim 8, wherein between step 2 and step 4, the spot size and/or heating power of the laser heating unit are/is changed to adjust the magnitude of the radial temperature gradient in the plane with the magnetic thin-film microstructure, the corresponding magnetic field sensitivity coefficient is re-obtained, and the magnetic field microprobe under different sensitivity conditions is applied to magnetic field measurement on magnet surfaces, non-contact current measurement, geomagnetic detection, biomagnetic imaging, or electronic compasses.
